(19) United States
(12) Patent Application Publication
(10) Pub. No.: US 2009/0217520 A1
(43) Pub. Date: Sep. 3, 2009

(54) METHOD FOR FORMING SOLDER LUMPS ON PRINTED CIRCUIT BOARD SUBSTRATE

(75) Inventors: FENG-YAN HUANG, Shenzhen City (CN); YUNG-WEI LAI, Tayuan (TW); SHING-TZA LIOU, Tayuan (TW)

Correspondence Address: PCE INDUSTRY, INC.;ATT. Steven Reiss, 458 E. LAMBERT ROAD, FULLERTON, CA, 92835, US

(73) Assignees: FUKUI PRECISION COMPONENT (SHENZHEN) CO., LTD., Shenzhen City (CN); FOXCONN ADVANCED TECHNOLOGY INC., Tayuan (TW)

(21) Appl. No.: 12/266,801

(22) Filed: Nov. 7, 2008

(30) Foreign Application Priority Data
Feb. 29, 2008 (CN) 200810300430.X

(51) Int. Cl. H05K 3/10

(52) U.S. Cl. 29/846

(57) ABSTRACT

In this present invention, a method for forming solder lumps on printed circuit board (PCB) substrate is provided. A PCB substrate including a number electrical traces and solder pads formed on a substrate surface thereof is provided. A liquid photoresist is applied onto the PCB substrate such that a photoresist layer defining a number of openings thereof is formed and each of the solder pads is exposed via each of the openings. A solder masses are filled into each of the openings. The solder masses are reflowed and the photoresist layer is removed.

### BACKGROUND

1. Technical Field

The present invention generally relates to printed circuit board packaging technology, and particularly relates to a method for forming solder lumps on a printed circuit board substrate.

2. Discussion of Related Art

In printed circuit board (PCB) manufacturing, prior to a welding process, a solder lump is formed on a corresponding solder pad which is defined in a predetermined region of a PCB substrate. A typical method for forming the solder lump on the PCB substrate includes the following steps. Firstly, a mask defining a number of through-holes therein is placed onto a surface of the PCB substrate. Each of the through-holes corresponds to a solder pad of the PCB substrate. Secondly, the through-holes are filled with a solder masses using a screen printing process. Thirdly, the solder masses in each of the through-holes are reflowed so that the solder pad is substantially covered by the melted metal masses. Finally, the mask is separated from the PCB substrate, thus obtaining a PCB substrate having a number of solder lumps formed thereon.

However, the method described above has the following disadvantages. First, some of the solder massess in the through-holes may be peeled from the PCB substrate during the separation of the mask. As a result, the solder masses accommodated in the through-holes for forming solder lumps is insufficient. Second, precision of the screen printing process is generally in a range from 20 microns to 25 microns, so using the screen printing process for filling the though-holes with metal is not suitable for forming solder lumps on a PCB substrate having a line width less than 0.3 millimeters.

What is needed, therefore, is a method for forming solder lumps on a printed circuit board substrate to overcome the above-described problems.

### SUMMARY

One embodiment provides a method for forming solder lumps on printed circuit board substrate. Firstly, a PCB substrate including a number of electrical traces and solder pads formed on a substrate surface thereof is provided. Secondly, a liquid photoresist is applied onto the PCB substrate such that a photoresist layer defining a number of openings therein is formed and each of the solder pads is exposed via the openings. Thirdly, each of the openings is filled with a solder masses. Fourthly, the solder massess are reflowed. Lastly, the photoresist layer is removed.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of embodiments. Moreover, in the drawings, like reference numerals designate corresponding parts throughout the different views.

FIG. 1 is a flow chart of a method for forming solder lumps on a printed circuit board substrate according to an exemplary embodiment.

FIG. 2 is an isometric view of a printed circuit board substrate having a number of electrical traces and solder pads.

FIG. 3 is a cross-sectional view of the substrate of FIG. 2, taken along a line III-III.

FIG. 4 is similar to FIG. 3, but showing a mask placed on the substrate.

FIG. 5 is similar to FIG. 4, but showing a photoresist layer formed on the substrate.

FIG. 6 is similar to FIG. 5, but showing the mask is removed.

FIG. 7 is similar to FIG. 6, but showing solder masses received in openings of the photoresist layer.

FIG. 8 is similar to FIG. 7, but showing a reflowing step.

FIG. 9 is similar to FIG. 8, but showing the photoresist layer is removed.

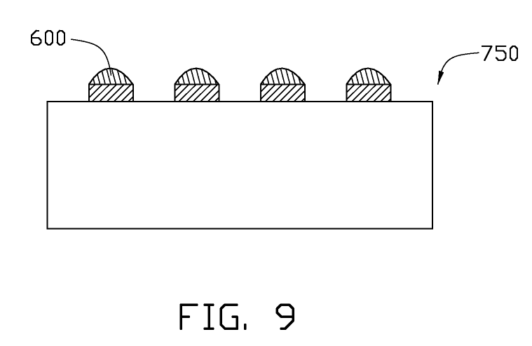

FIG. 10 is a cross-sectional view showing mounting a chip onto the substrate according to an exemplary embodiment.

### DETAILED DESCRIPTION OF EMBODIMENTS

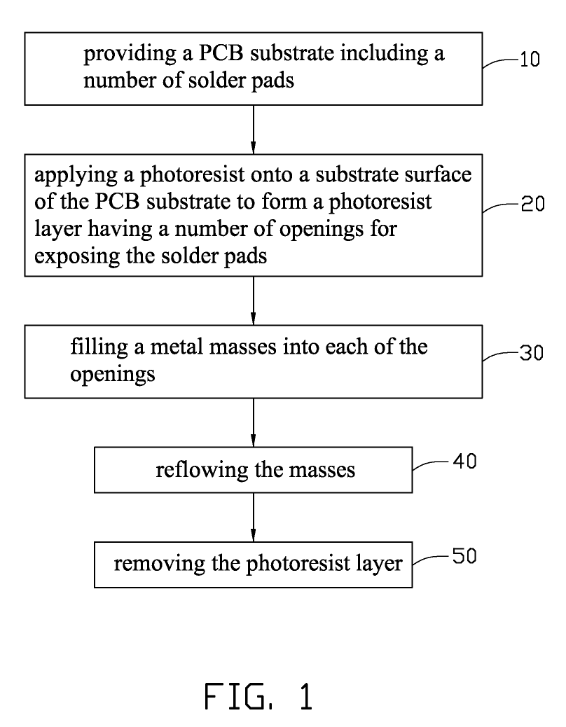

FIG. 1 illustrates a method for forming solder lumps on a PCB substrate. The method will be discussed in detail with the following exemplary embodiment.

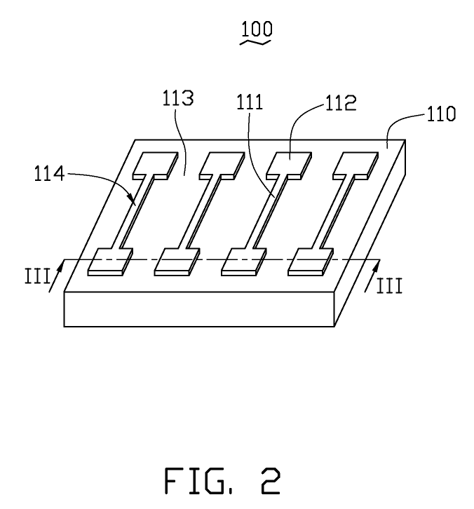

Referring to FIG. 2, in step 10, a printed circuit board (PCB) substrate 100 is provided. The PCB substrate 100 has a number of electrical traces 111 and a number of solder pads 112 electrically connected to the electrical traces 111. The PCB substrate 100 has a substrate surface 110. The electrical traces 111 and the solder pads 112 are formed on the substrate surface 110, thus defining a peripheral area 113 between two neighboring electrical traces 111 and the solder pads 112. The electrical traces 111 have a second surface 114. In this embodiment, a distance between adjacent electrical traces 111, i.e., a line width of the PCB substrate 100 is in a range from about 5 micrometers to about 100 micrometers.

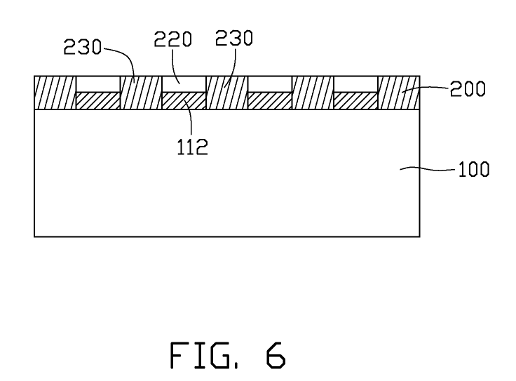

In step 20, as shown in FIG. 6, a photoresist layer 200 having a number of openings 220 is formed on the PCB substrate 100, while each solder pad 112 is exposed via a corresponding opening 220.

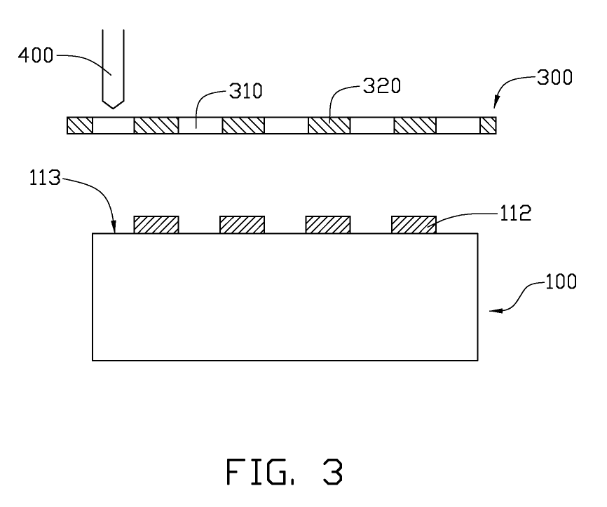

In detail, referring to FIG. 3, a mask 300 and an ejecting device 400 are provided. The mask 300 includes a number of covering portions 320 and a number of through-holes 310 penetrating through the mask 300 between the covering portions 320. The covering portions 320 are configured for covering the solder pads 112. The ejecting device 400 is configured for ejecting liquid photoresist onto the second surface (not shown) and the peripheral area 113.

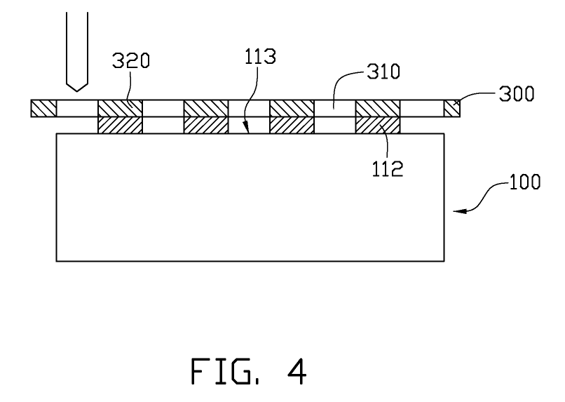

As shown in FIG. 4, the mask 300 is placed onto the PCB substrate 100, and all the solder pads 112 are substantially covered by the covering portion 320 while the electrical traces (not shown) and the peripheral area 113 are exposed via the through-holes 310.

Referring to FIGS. 4˜5, a liquid photoresist is applied onto the peripheral area 113 and the electrical traces (not shown) via the through-holes 310 and fills the through-holes 310. Then the liquid photoresist is quickly solidified, thus obtaining the photoresist layer 200 having a number of photoresist members 230. A thickness of the photoresist members 230 is more than that of the solder pads 112.

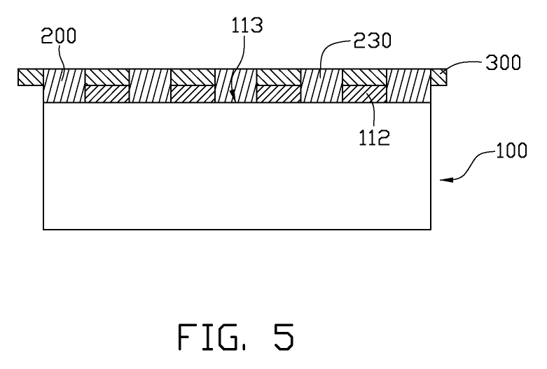

Referring to FIGS. 5˜6, the mask 300 is removed from the photoresist layer 200. Therefore, each two adjacent photoresist members 230 and the solder pad 112 located therebetween cooperatively define an opening 220 for accommodating a solder masses in a following step.

In step 30, referring to FIGS. 6˜7, the openings 220 are filled with a solder masses 500 using a typical screen printing method or a known depositing process. In the present embodiment, a screen printing method is used. The metal masses 500 are comprised of tin or other metal which has low molten temperature.

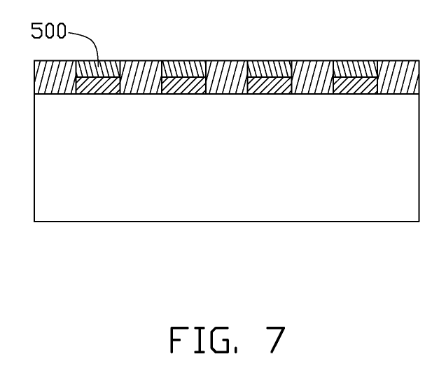

In step 40, referring to FIGS. 7˜8, the solder masses 500 are treated using a typical reflow soldering process to obtain a number of solder lumps 600 formed on the solder pads 112. In this manner, the solder lumps 600 substantially cover the solder pads 112.

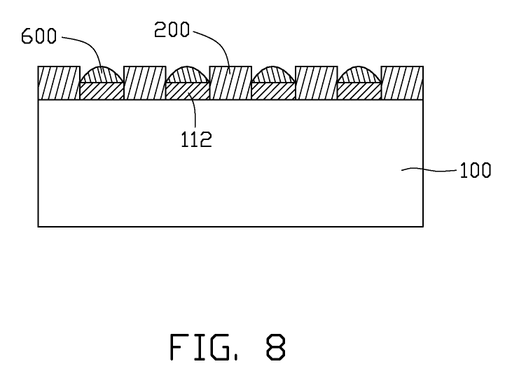

In step 50, referring to FIGS. 8˜9, the photoresist layer 200 is removed from the PCB substrate 100 using a chemical etching method, thus obtaining a printed circuit board 750 having a number of solder lumps 600.

In another embodiment, the photoresist layer 200 is formed using an ink injection method. In detail, firstly, an ink jet device with a micro-electro mechanical system (MEMS) is provided. Secondly, positions of the second surface and the peripheral area are stored in the MEMS. Finally, a liquid photoresist is applied onto the second surface and the peripheral area under a controlling signal from the MEMS and quickly solidifies.

A method for flip chip packaging using one of the above described methods of forming solder lumps will be described below with an example of packaging a chip onto the PCB substrate 100.

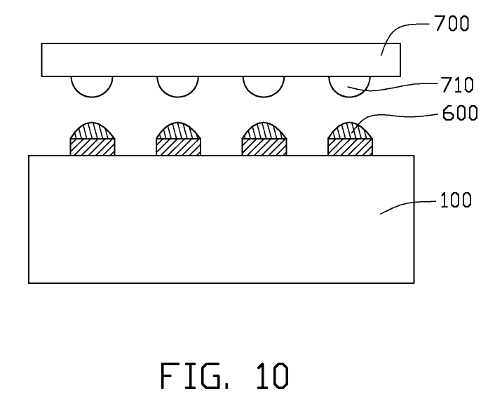

As shown in FIG. 10, the flip chip packaging method includes following steps. Firstly, a number of solder lumps 600 are formed on a predetermined region of the PCB substrate 100 using the aforesaid method. Secondly, a chip 700 having a number of solder members 710 is provided. Each of the solder members 710 corresponds to each of the solder lumps 600. Thirdly, each of the solder members 710 is connected to the corresponding solder performs 600 using a welding process, thus obtaining a package of the chip 700 and the PCB substrate 100.

While certain embodiments have been described and exemplified above, various other embodiments will be apparent to those skilled in the art from the foregoing disclosure. The present invention is not limited to the particular embodiments described and exemplified but is capable of considerable variation and modification without departure from the scope of the appended claims.

What is claimed is:

1. A method for forming solder lumps on a printed circuit board (PCB) substrate, comprising:
providing a PCB substrate including a substrate surface, a plurality of electrical traces and a plurality of solder pads for placement of solder lumps thereon, the electrical traces and solder pads formed on the substrate surface;
forming a photoresist layer on the substrate surface, the photoresist layer covering the electrical traces, the photoresist layer defining a plurality of openings, the solder pads exposed via the respective openings;
filling the openings in the photoresist layer with solder masses;
reflowing the solder masses thereby obtaining the solder lumps formed on the corresponding solder pads; and
removing the photoresist layer.

2. The method as claimed in claim 1, wherein a distance between adjacent electrical traces is in a range from 5 micrometers to 100 micrometers.

3. The method as claimed in claim 1, further comprising providing a mask with a plurality of through-holes, the mask configured for covering the solder pads and exposing the electrical traces; and attaching the mask to the substrate surface such that the electrical traces are exposed via the respective through-holes and the solder pads are covered.

4. The method as claimed in claim 1, wherein the photoresist layer is applied onto the substrate surface using an ink injecting process.

5. The method as claimed in claim 1, wherein the solder masses are applied into the openings using a screen printing process.

6. The method as claimed in claim 1, wherein the photoresist layer is removed using a chemical etching method.

7. A method comprising:
providing a PCB substrate including a substrate surface, a plurality of electrical traces and a plurality of solder pads for placement of solder lumps thereon, the electrical traces and solder pads formed on the substrate surface;
forming a photoresist layer on the substrate surface, the photoresist layer covering the electrical traces, the photoresist layer defining a plurality of openings, the solder pads exposed via the respective openings;
filling the openings in the photoresist layer with solder masses;
reflowing the solder masses thereby obtaining the solder lumps formed on the corresponding solder pads;
removing the photoresist layer; and
mounting an electronic chip onto the PCB substrate, the electronic chip electrically soldered to the solder lumps.

8. The method as claimed in claim 7, wherein a distance between adjacent electrical traces is in a range from 5 micrometers to 100 micrometers.

9. The method as claimed in claim 7, further comprising providing a mask with a plurality of through-holes, the mask configured for covering the solder pads and exposing the electrical traces; and attaching the mask to the substrate surface such that the electrical traces are exposed via the respective through-holes and the solder pads are covered.

10. The method as claimed in claim 7, wherein the photoresist layer is applied onto the substrate surface using an ink injecting process.

11. The method as claimed in claim 7, wherein the solder masses are applied into the openings using a screen printing process.

12. The method as claimed in claim 7, wherein the photoresist layer is removed using a chemical etching method.
